(19) United States
(12) Patent Application Publication
(10) Pub. No.: US 2024/0213940 A1
(43) Pub. Date: Jun. 27, 2024

(54) ELECTRIC CIRCUIT PROVIDING MIXING AND GAINING FUNCTIONS FOR A RF RECEIVER FRONT-END AND RF RECEIVER FRONT-END

(71) Applicant: CSEM Centre Suisse d'Electronique et de Microtechnique SA Recherche et Développement, Neuchâtel (CH)

(72) Inventor: Konstantinos Manetakis, Neuchâtel (CH)

(21) Appl. No.: 18/543,264

(22) Filed: Dec. 18, 2023

(30) Foreign Application Priority Data
Dec. 23, 2022 (EP) 22216554.0

(51) Int. Cl. H03F 3/45

(52) U.S. Cl. CPC H03F 3/45475; H03F 2200/129; H03F 2200/171; H03F 2200/294; H03F 2200/451

(57) ABSTRACT

An electric circuit providing mixing and gaining functions for a RF receiver front-end, including an I path and a Q path. Each of the I path and Q path includes: a switch, an input capacitor between the switch and an input of an operational amplifier, and a feedback capacitor between the input and the output of the operational amplifier. The electric circuit includes: a local oscillator arranged to generate a carrier signal having a carrier frequency, a command module arranged to sequentially close each switch during a mixer's averaging window, so that an incoming signal having a frequency close to the carrier frequency results in a non-zero down-converted signal across the input capacitor. This down-converted signal is amplified by the operational amplifier so that an amplified down-converted signal appears at the output of the operational amplifier. A RF front-end is inductor-less, includes a linearity optimized LNA, and/or has reconfigurable topology.

### TECHNICAL DOMAIN

The present invention concerns an electric circuit providing mixing and gaining functions for a RF receiver front-end and a RF receiver front-end.

### RELATED ART

RF receivers are arranged to receive RF signals, i.e. signals having an RF frequency. In this context, an RF frequency is a frequency between 3 kHz and 300 GHz, in particular between 300 MHz and 100 GHz.

A known RF receiver is illustrated in FIG. 1. It comprises an antenna 70, followed in general by a balun 60. The antenna 70 in the example of FIG. 1 is shared with a power amplifier (PA) 50 of an RF transmitter. In the example of FIG. 1, the PA has a differential output. The antenna interface and sharing with the transmitter can be designed so that to enable large PA output powers. Each output of the PA can be connected to the ground by a capacitor C in series with a switch SW. The received RF signal is then amplified by a Low Noise Amplifier (LNA) 10. The LNA 10 can be preceded by an electrostatic discharge device (ESD) 80 and/or by a resistor R connected to the ground by a switch SW that acts as an attenuator.

The frequency of the amplified RF signal then is translated to a lower frequency, e.g. to an intermediate frequency (IF) which is lower than an RF frequency, or to a baseband frequency, by a mixer 20, so that the mixed signal can be processed further. Therefore, the mixer 20 in a RF receiver is a down-converting mixer.

A mixer 20 is in general connected to an oscillator (LO) 40 arranged for generating a carrier signal, having a carrier frequency.

The RF signal received at the antenna 70 is in general modulated and comprises an in-phase component and a quadrature-phase component. Therefore, the mixer 20 comprises in general a I path (I) and a Q path (Q), for processing the in-phase component and the quadrature-phase component of the received RF signal respectively.

An RF receiver front-end 1 comprises in general the LNA 10 and the mixer 20. The mixer 20 is in general followed by a (base-band) filter 30. The base-band filtered signal is then in general converted to a digital signal by an analog-to-digital converter (ADC), not illustrated in FIG. 1.

The mixer 20 can be active or passive. Active mixers have a power gain, which is in general provided by using active device(s) or transconductance stage(s).

One advantage of active mixers is that their power gain reduces the contribution of the noise of the subsequent blocks. However, their linearity can be poor. The well-known Gilbert mixer is a typical example of an active mixer.

Passive mixers usually comprise a commutating device (e.g. a switch or a diode) that has no bias current. Passive mixers have zero power gain.

Passive mixers can be current-mode mixers respectively voltage-mode mixers. In current-mode mixers, commutating devices are used for switching currents. In voltage-mode mixers, commutating devices are used for switching voltages.

Passive mixers have become the solution of choice in recent times primarily for their low flicker noise, high linearity (mostly related to the absence of a transconductance stage), low power consumption and speed. However, the use of those passive mixers needs large gain further down in the receiver chain.

Moreover, they are not well adapted to low power applications, i.e. to applications consuming power lower than few mW, which require no amplification after the mixer. In fact, in those applications, the mixer is active so that no gain is necessary after the mixer.

Concerning the whole RF front-end, common issues of existing RF receiver front-ends comprise the used silicon area, the power dissipation, the linearity, the noise and/or the sensitivity.

### SHORT DISCLOSURE OF THE INVENTION

An aim of the present invention is the provision of an electric circuit for a RF receiver front-end, which allows to solve or mitigate at least one of the issues of existing electric circuits.

Another aim of the present invention is the provision of an electric circuit for a RF receiver front-end, which is adapted to low power applications.

Another aim of the present invention is the provision of an electric circuit for a RF receiver front-end, which has a relatively low noise.

Another aim of the present invention is the provision of an electric circuit for a RF receiver front-end, which has a good linearity.

Another aim of the present invention is the provision of an electric circuit for a RF receiver front-end, which is alternative to the known electric circuits.

Another aim of the present invention is the provision of a RF receiver front-end, which allows to solve or mitigate at least one of the RF receiver front-end's mentioned issues.

According to the invention, these aims are attained by the object of the attached claims, and especially by an electric circuit for a front-end of a RF receiver according to claim 1, and by a RF receiver front-end according to claim 6.

The electric circuit providing mixing and gaining functions for a RF receiver front-end according to the invention comprises an I path and a Q path, wherein each of the I path and the Q path comprises:
a switch,
an input capacitor between the switch and an input of an operational amplifier,
the operational amplifier,
a feedback capacitor between the input and the output of the operational amplifier,
   the electric circuit comprising:
a bias resistor so as to DC-bias the operational amplifier input,
a local oscillator connected to the mixer and arranged to generate a carrier signal having a carrier frequency,
a command module arranged to sequentially close each switch during a mixer's averaging window, so that an incoming signal having a frequency close to the carrier frequency, i.e. a frequency belonging to a mixer bandwidth, results in a non-zero down-converted signal across the input capacitor, this down-converted signal being then amplified by the operational amplifier so that an amplified down-converted signal appears at the output of the operational amplifier.

In one embodiment, the mixer bandwidth is given by the formula:

$$BW = 2 \frac{1}{2 π \cdot 4 ( {R}_{S} + {R}_{SW} ) {C}_{1}} ,$$

wherein
R_{S} is the resistance of a source resistor connected to the switch,
R_{SW} is the resistance of each switch once it is closed
C₁ is the capacitance of each input capacitor.

In this context, the expression “sequentially close” indicates that only a switch can be closed at a time. In one preferred embodiment, the mixer's averaging window is equal to the carrier period T_{LO} divided by the total number of the switches of the I and Q paths. For example, if each of the I and Q path comprises one switch, then there are two switches: the mixer's averaging window is equal to a half of the carrier period (T_{LO}/2). Therefore, a first switch will be closed during the first half of the carrier period (the second switch being open), and the second switch will be closed during the second half of the carrier period (the first switch being open), those two halves of the carrier period being not overlapping.

The electric circuit providing mixing and gaining functions according to the invention comprises a mixer which is an averaging mixer, i.e. it is arranged for averaging an incoming signal. It does not commutate or sample, it averages the incoming signal. In other words, the mixing operation is performed by averaging on the input capacitors.

Signals close to the carrier frequency and its harmonics are in-sync with the carrier signal. They thus move slowly through the mixer's averaging window resulting in non-zero output. In other words, if the incoming signal is close in frequency to the carrier signal, then the averaging results in a finite output (the signal looks nearly the same every time the carrier looks at it, so the average is non-zero).

Signals far away (i.e. not close) from the carrier frequency and its harmonics move fast through the mixer's averaging window resulting in zero output. In other words, if the signal is far away in frequency from the carrier signal, the averaging results in zero output.

The electric circuit according to the invention provides a gain. In other words, the electric circuit according to the invention provides simultaneously mixing and gaining functions. Since it provides a gain, then it reduces the overall power by relaxing the need for large gain further down in the receiver chain.

Therefore, the electric circuit according to the invention is well adapted to low power applications.

Moreover, the electric circuit according to the invention has a relatively low noise and a good linearity.

In the electric circuit according to the invention, a down-converted baseband (or IF) signal appears across input capacitors (C₁). An amplified down-converted baseband (or IF) signal appears at the output of the operational amplifier. The voltage gain from the input capacitors (C₁) to the output of the operational amplifier is equal to C₁/C₂, wherein C₂ is the feedback capacitor.

In one embodiment, the operational amplifier is a fully differential operational amplifier, the switch is a first switch, the input capacitor is a first input capacitor, the input is a first input, the output is a first output, the mixer's averaging window is a first mixer's averaging window and each of the I path and the Q path comprises:
a second switch,
a second input capacitor between the second switch and a second input of the differential operational amplifier,
a second feedback capacitor between the second input and a second output of the operational amplifier.

In this embodiment, the command module is arranged to sequentially close each switch during a second mixer's averaging window, so that said incoming signal results in a non-zero down-converted signal across the input capacitors, this down-converted signal being then amplified by the differential operational amplifier so that an amplified down-converted signal appears at the first and second outputs of the differential operational amplifier.

In this embodiment, each of the I and Q path comprises two switches, then there are four switches: the mixer's averaging window is equal to a quarter of the carrier period (T_{LO}/4). Therefore, a first switch will be closed during the first quarter of the carrier period (the other three switches being open), a second switch will be closed during the second quarter of the carrier period (the other three switches being open), a third switch will be closed during the third quarter of the carrier period (the other three switches being open) and a fourth switch will be closed during the fourth quarter of the carrier period (the other three switches being open), those four quarters of the carrier period being not overlapping.

In one embodiment, the feedback capacitor(s) is(are) variable feedback capacitor(s), so as to have a variable gain. This helps to reduce power dissipation in the analog baseband.

In one embodiment, by controlling the variable feedback capacitor, the gain from RF to the frequency translated I/Q outputs can be set to 18 dB, 12 dB or 6 dB.

In one embodiment, the bias resistor is connected to the input(s) of the operational amplifier, so as to DC-bias the operational amplifier inputs. In one embodiment, the bias resistor is large, i.e. its resistance is larger than 25 KΩ.

In one embodiment, the bias resistor is a feedback resistor(s) is(are)across each feedback capacitor(s). This allows to introduce a zero (at zero frequency) and a pole (at 1/(R_{B}C₂)) in the baseband (or IF) signal transfer function. In one embodiment, the feedback resistor is large, i.e. its resistance is larger than 250 KΩ.

In one embodiment, the feedback resistor(s) is(are) selected so that a pole in a frequency translated signal transfer function is at least 5 times lower in frequency than the wanted frequency translated signal for the gain settings.

In one embodiment, the mixer comprises a resistor (Rₚ) between each input capacitor and the corresponding input of the operational amplifier, so as to introduce a pole in the frequency translated transfer function. This pole helps to simplify the filtering done in the analog baseband circuitry that follows the mixer.

In one embodiment, a gate of each switch is coupled, preferably AC-coupled, to at least one of the LOs. The switch is not necessarily directly coupled to the LOs. For example, a control block could be present between the LOs and the gates, so as to generate the phases.

In one embodiment, the switches have a low or zero on-resistance, and are arranged to turn off well (good isolation). A practical implementation uses MOS devices as switches.

In one embodiment, the electric circuit comprises at least one digital-to-analog converter (DAC) for controlling the dc-level at the gates.

The present invention also concerns a RF receiver front-end, comprising:
an LNA,
the electric circuit according to the invention, connected to an output of the LNA.

In one embodiment, the LNA comprises a current-reuse common-source stage, the current-reuse common-source stage comprising:
a p-type transistor,
a n-type transistor sharing a variable current with the p-type transistor,
a gain resistor (R_{G}) between a gate and a drain of the p-type transistor,
a first capacitor connected to the gate of the p-type transistor,
a second capacitor connected to the gate of the n-type transistor,
a p-type bias voltage control module, comprising a first switch and a p-type bias voltage transistor, the first switch being between a source terminal of the p-type bias voltage transistor and a source terminal of the p-type transistor, a gate and a drain of the p-type bias voltage transistor being connected to the gate and the drain of the p-type transistor,
a n-type bias voltage control module, comprising a second switch and a n-type bias voltage transistor, the second switch being between a source terminal of the n-type bias voltage transistor and a source terminal of the n-type transistor, a gate and a drain of the n-type bias voltage transistor being connected to a gate and a drain of the n-type transistor.

The LNA of this embodiment comprises also a command module arranged to control the first switch and the second switch, so as to operate the current-reuse common-source stage under constant current density, so as to obtain a constant linearity.

Therefore, the RF front-end according to this embodiment presents many advantages: first, the LNA is devoid of inductors. Since the electric circuit is also devoid of inductors, the RF receiver front-end silicon area is drastically reduced since the RF receiver front-end is an inductor-less RF receiver front-end.

Second, the LNA is arranged to operate at constant current density to optimize linearity.

Third, bias current control of the LNA allows to tradeoff power dissipation for sensitivity. In other words, it is possible to maintain a known sensitivity performance, while reducing power dissipation.

In one embodiment, the LNA comprises at least two p-type bias voltage control modules and/or at least two n-type bias voltage control modules.

In one embodiment, the current-reuse common-source stage comprises a gain control module, wherein the gain control module comprises at least one gain control resistor in series with a third switch, the series of the gain control resistor with the third switch being in parallel to the gain resistor (R_{G}).

In one embodiment, the p-type transistor and the n-type transistor are operated in a moderate inversion, so as to optimize the third order input intercept point (IIP3) of the LNA.

In one embodiment, the current-reuse common-source stage is a first current-reuse common-source stage, the LNA comprising a second current-reuse common-source stage in series with the first current-reuse common-source stage. This allows to drive the mixer with an elevated impedance (a few hundred Ohms), which in general is beneficial for both the noise and the linearity performance of the mixer.

In one embodiment, the front-end comprises a baseband (or IF) amplifier, connected to an output of the electric circuit and arranged so as to provide a baseband gain depending on the LNA gain and on the mixer gain, e.g. so as to have a given total gain of the front-end.

In one embodiment, the baseband (or IF) amplifier is a baseband (or IF) filter.

In one embodiment, the baseband (or IF) filter is arranged to be configured as a two pole filter, as a single pole filter or it can be bypassed, so as to trade-off its sharpness for power dissipation. In this embodiment, the baseband (or IF) filter has then a reconfigurable topology that saves power in the analog baseband (or IF) at the expense of the carrier to interference ratio (C/I) and/or alias attenuation.

In one embodiment, the two pole filter is a polynomial filter, e.g. a Tow-Thomas filter.

In one embodiment, the baseband (or IF) filter is a first stage baseband (or IF) filter, the front-end comprising a second stage baseband (or IF) filter in series with the first stage baseband (or IF) filter.

In one embodiment, the first stage baseband (or IF) filter has a quality factor lower than the second stage baseband (or IF) filter.

### SHORT DESCRIPTION OF THE DRAWINGS

Exemplar embodiments of the invention are disclosed in the description and illustrated by the drawings in which:

FIG. 1 illustrates a known RF receiver.

FIG. 2 illustrates the operation basics of a part of the electric circuit according to the invention.

FIG. 3 illustrates the differential gain from the harmonic n to the baseband (or IF) as a function of the harmonic number n of one embodiment of the part of the electric circuit of FIG. 2.

FIG. 4 illustrates another embodiment of the operation basics of a part of the electric circuit according to the invention, in particular for computing its bandwidth and/or its noise.

FIG. 5 illustrates another embodiment of the operation basics of a part of the electric circuit according to the invention, in particular for computing its RF impedance.

FIG. 6 illustrates a schematic representation of an embodiment of a part of the electric circuit according to the invention, in particular for computing its linearity.

FIG. 7 illustrates an embodiment of the electric circuit according to the invention.

FIG. 8 illustrates another embodiment of the electric circuit according to the invention.

FIG. 9 illustrates another embodiment of the electric circuit according to the invention.

FIG. 10 illustrates an embodiment of how to drive the switches of the electric circuit according to the invention.

FIG. 11 illustrates an embodiment of the LNA of the RF receiver front-end according to the invention.

FIG. 12 illustrates an embodiment of a part of a stage of the LNA of the RF receiver front-end according to the invention

FIG. 13 illustrates the drain current (I_{D}) of an embodiment of the LNA MOS device of the RF receiver front-end according to the invention, as a function of the gate-source voltage (V_{GS}) of this LNA MOS device, for showing a general continuous model for a LNA MOS device.

FIG. 14 illustrates the first-order transconductance (g₁), the second-order transconductance (g₂) and the third-order transconductance (g₃) of an embodiment of the LNA MOS device of the RF receiver front-end according to the invention, as a function of the gate-source voltage (V_{GS}) of this LNA MOS device.

FIG. 15 illustrates the IIP3, the second order input intercept point (IIP2) and the drain current (I_{D}) of an embodiment of the LNA MOS device of the RF receiver front-end according to the invention, as a function of the gate-source voltage (V_{GS}) of this LNA MOS device.

FIG. 16 illustrates an embodiment of the baseband (or IF) filter of the RF receiver front-end according to one embodiment of the invention.

FIG. 17A illustrates a first possible configuration of the baseband (or IF) filter of FIG. 16.

FIG. 17B illustrates a second possible configuration of the baseband (or IF) filter of FIG. 16.

FIG. 18 illustrates another embodiment of the baseband (or IF) filter of the RF receiver front-end according to one embodiment of the invention.

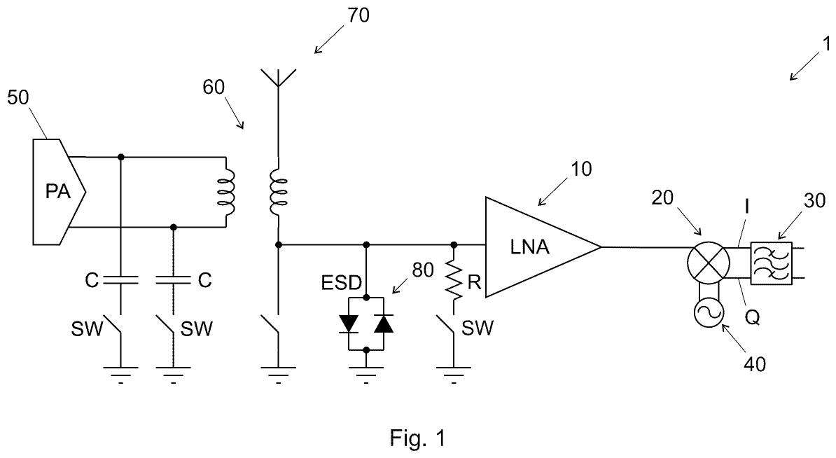

### EXAMPLES OF EMBODIMENTS OF THE PRESENT INVENTION

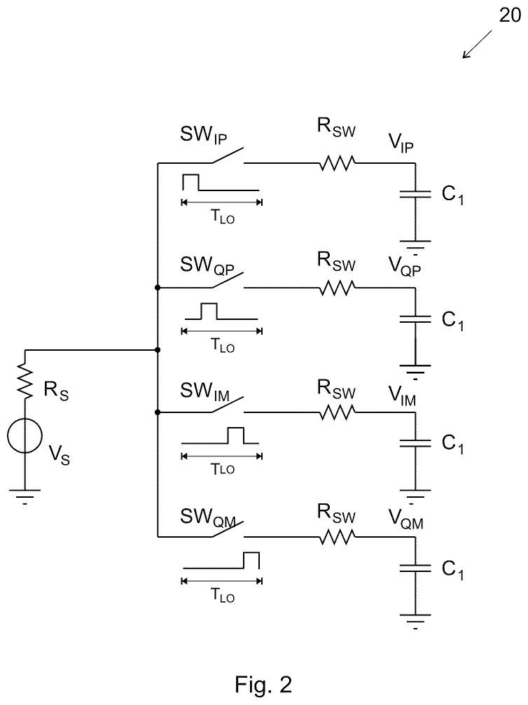

FIG. 2 illustrates the operation basics of a part of the electric circuit 20 according to the invention (the operational amplifier, the feedback capacitor and the command module are not represented).

The electric circuit 20 of FIG. 2 operates by RC filtering (averaging) the incoming RF carrier (which has been schematically indicated by a voltage source V_{S} followed by a resistor R_{S}) over a time window.

In one embodiment, this time window is equal to T_{LO}/2, wherein T_{LO} is the period of the signal generated by a LO (not-illustrated) connected to the electric circuit 20.

In the illustrated embodiment, wherein the electric circuit 20 comprises a fully differential operational amplifier (not illustrated in FIG. 2), this time window is equal to T_{LO}/4.

In the embodiment of FIG. 2, the electric circuit 20 comprises two paths for the in-phase component of the received signal (the first and the third starting from the top of FIG. 2), and two paths for the quadrature-phase component of the received signal (the second and the fourth starting from the top of FIG. 2).

In the embodiment of FIG. 2, the I path switch SW_{IP} will be closed for a first ¼ of a LO period of the LO connected to the mixer, the Q path switch SW_{QP} will be closed for a second ¼ of the LO period, the I path bar switch SW_{IM} will be closed for a third ¼ of a LO period, the Q path bar switch SW_{QM} will be closed for a fourth ¼ of the LO period, and that those four ¼ LO periods do not overlap. Any other order of closing of those four switches could be used, as long as the four ¼ LO periods do not overlap.

Once closed, each switch of FIG. 2 presents a resistance R_{SW}, which has been illustrated in series to each switch, for representing the fact that it is not ideal.

Signals close to the LO frequency and its harmonics are in-sync with the LO. They thus move slowly through the averaging window resulting in non-zero output.

Signals far away from the LO frequency and its harmonics move fast through the averaging window resulting in zero output.

Non-zero outputs of the electric circuit 20 comprise the four voltages V_{IP}, V_{QP}, V_{IM}, V_{QM} across capacitors C₁, which are the input capacitors of the electric circuit according to the invention, arranged to be connected to an operational amplifier.

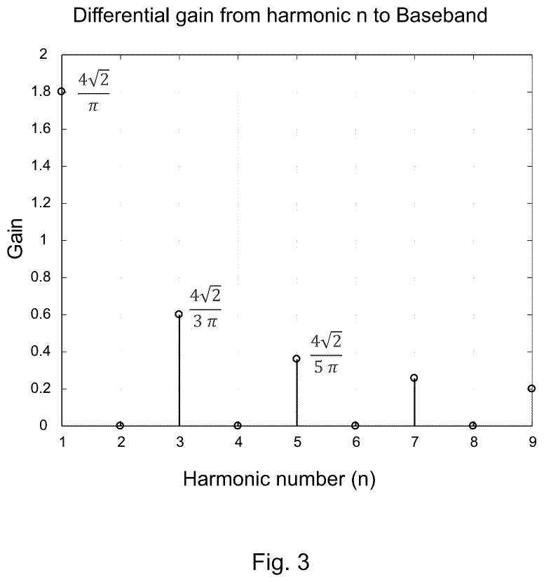

FIG. 3 illustrates the differential gain from the harmonic n to the baseband (or IF) as a function of the harmonic number n of one embodiment of the part of the electric circuit 20 of FIG. 2.

Due to the “averaging” operation, the conversion voltage gain from harmonic n to baseband (or IF) can be estimated by:

$${G}_{n} = \frac{{V}_{IP}}{{V}_{s}} {\vert}_{n} = \frac{2}{π} {\int }_{{φ}_{o}}^{{φ}_{o + \frac{π}{2}}} sin ( n φ ) d φ \qquad ( 1 )$$

wherein φ₀ is a phase chosen to maximize the integral of formula (1), in order to obtain the peak value of the down-converted signal.

When looking at the output differentially, the voltage gains from even harmonics cancel out.

Therefore, there is a non-zero differential voltage gain only from the odd-harmonics with values as shown in the FIG. 3.

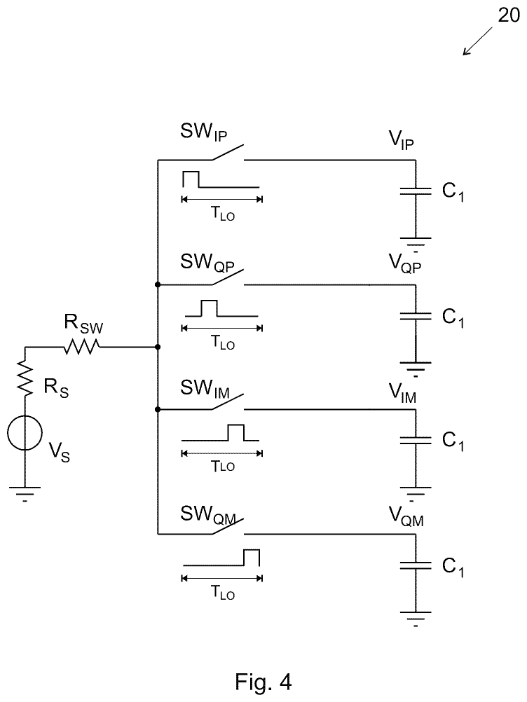

FIG. 4 illustrates another embodiment of the operation basics of a part of the electric circuit according to the invention, in particular for computing its bandwidth and/or its noise, wherein the switch resistor R_{SW} has been pulled out.

Each capacitor C₁ is charged successively by V_{S} via the total resistor R_{S}+R_{SW}.

In the embodiment of FIG. 4, each capacitor C₁ “sees” V_{S} during only one-fourth of the LO period, therefore the effective charging resistance is 4·(R_{S}+R_{SW}).

It is therefore expected a 3 dB baseband bandwidth BW (−3 dB to −3 dB) that is given by:

$$BW \approx 2 \frac{1}{2 π \cdot 4 ( {R}_{S} + {R}_{SW} ) {C}_{1}} \qquad ( 2 )$$

As the bandwidth BW of formula (2) depends on the source resistor R_{S}, in one embodiment this resistor should be kept far beyond the baseband (or IF) frequency operation range.

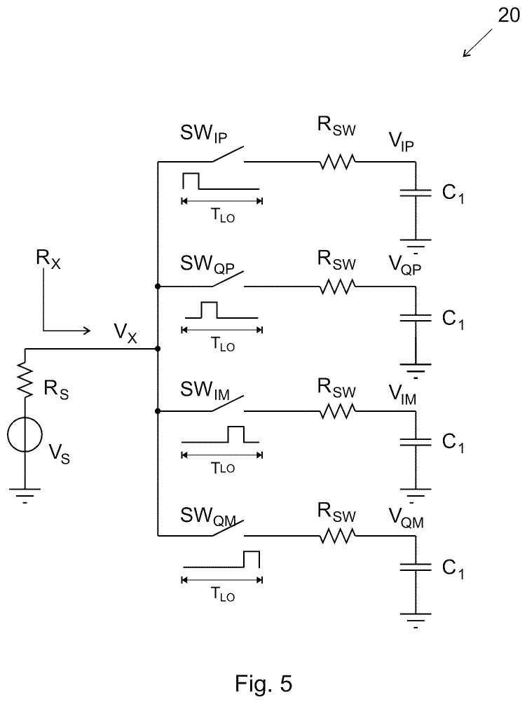

FIG. 5 illustrates another embodiment of the operation basics of a part of the electric circuit according to the invention, in particular for computing its RF impendence Rₓ, and then S11.

Voltage Vₓ at harmonic n consists of two components.

The first component Vₓ|₁ is due to V_{S} and is given by the following formula:

$${V}_{x} {\vert}_{1} = {V}_{s} \frac{{R}_{SW}}{{R}_{SW} + {R}_{S}} \qquad ( 3 )$$

The second component Vₓ|₂ is due to the up-conversion of the baseband (or IF) signal stored on the capacitors C₁ back to RF via the switches and is given by the following formula, wherein n is the harmonic number:

$${V}_{x} {\vert}_{2} = ( {V}_{S} \frac{2 \sqrt{2}}{n π} ) ( \frac{{R}_{SW}}{{R}_{SW} + {R}_{S}} ) ( \frac{2 \sqrt{2}}{n π} ) \qquad ( 4 )$$

The input impedance Rₓ at LO harmonic n can then be estimated by the following formula for harmonics (odd n):

$${R}_{x} = \frac{{V}_{x}}{{V}_{S} - {V}_{x}} {R}_{S} = \frac{{R}_{SW} + {{R}_{S} ( \frac{2 \sqrt{2}}{n π} )}^{2}}{1 - {( \frac{2 \sqrt{2}}{n π} )}^{2}} \qquad ( 5 )$$

Furthermore, for n=2 the input impedance Rₓ is

$${R}_{x} = \frac{{R}_{SW} + {R}_{S} \frac{8}{{π}^{2}}}{1 - \frac{8}{{π}^{2}}} \qquad ( 6 )$$

For n=4 the input impedance Rₓ is:

$${R}_{x} = {R}_{SW} \qquad ( 7 )$$

Reverting back to FIG. 4, it is possible to compute the noise due to both R_{S} and R_{SW} down-converted from all the harmonics of the LO to baseband (or IF) according to the following formula:

$$\overline{{v}_{n}^{2}} {\vert}_{Ipm} = 2 \cdot 4 kT ( {R}_{S} + {R}_{SW} ) \cdot {\sum }_{n , odd} ( 2 \cdot {G}_{n}^{2} ) \approx 32 kT ( {R}_{S} + {R}_{SW} ) \qquad ( 8 )$$

wherein
T is the temperature
K is the Boltzmann's constant
Gₙ is the mixer gain at odd harmonic n as defined in formula (1).

The term Σ_{n,odd}(2·Gₙ²) is approximately equal to 4.

The factor of two in formula (8) accounts for the two sidebands either side of each carrier harmonic, and can be removed in the digital baseband (or IF).

Flicker noise from V_{S} adds directly but can be removed in practice with AC-coupling.

Therefore, the electric circuit according to the invention has a relatively low noise.

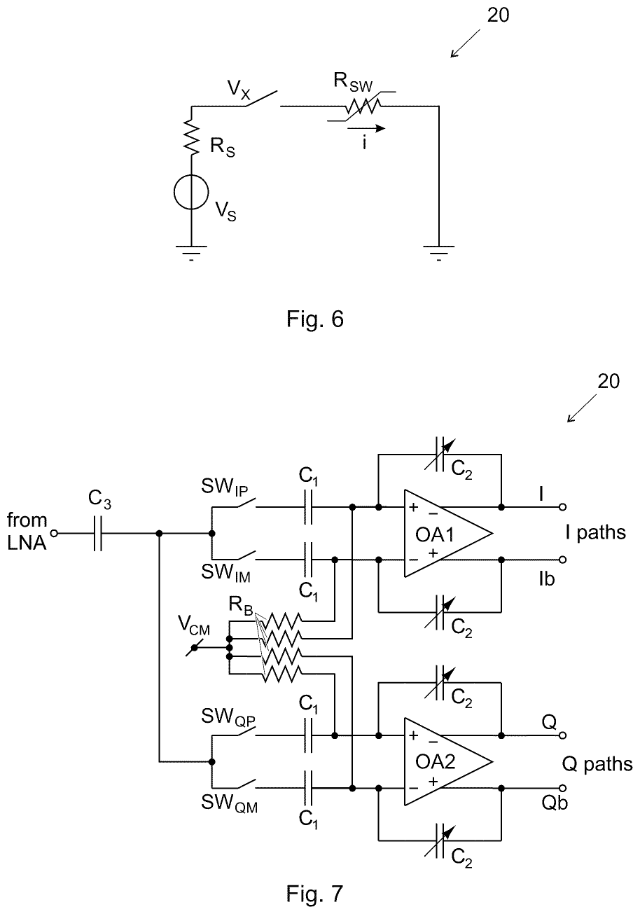

FIG. 6 illustrates a schematic representation of an embodiment of a part of the electric circuit 20 according to the invention, in particular for computing its linearity.

For non-overlapping mixer's averaging window, nonlinearity in the mixer is due to the switch nonlinear current-voltage relationship. The current i which flows through the non-ideal switch resistor RSW once it is closed is given by the following formula:

$$i \approx {g}_{1} {V}_{x} + {g}_{2} {V}_{x}^{2} + {g}_{3} {V}_{x}^{3} \qquad ( 9 )$$

wherein
Vₓ is the voltage across the switch (or at the electric circuit input)
g₁ is the first-order transconductance of the switch
g₂ is the second-order transconductance of the switch
g₃ is the third-order transconductance of the switch.

The IIP3 at the electric circuit input (Vₓ) can then be estimated by the following formula:

$$IIP 3 \approx \sqrt{\vert \frac{4 {( 1 + {g}_{1} {R}_{S} )}^{3}}{3 {R}_{S} {g}_{3}} \vert} \qquad ( 10 )$$

Simulations performed by the applicant confirm the formula (10) and allow to obtain an IIP3≈10 dBm.

Therefore, the electric circuit according to the invention has a good linearity (IIP3).

FIG. 7 illustrates an embodiment of the electric circuit 20 according to the invention, comprising an I path and a Q path, wherein each of the I path and the Q path comprises:
two switches (SW_{IP} and SW_{IM} respectively SW_{QP} and SW_{QM}),
an input capacitor C1 between each switch and an input of a fully differential operational amplifier OA1 respectively OA2,
the fully differential operational amplifier OA1 respectively OA2,
a feedback capacitor C₂ between each input and the output of the operational amplifier.

Although in the embodiment of FIG. 7 the operational amplifier is a fully differential operational amplifier, the electric circuit according to the invention is not limited to this fully differential operational amplifier but applies also to (non-fully differential) operational amplifiers. In this case, each of the I path and Q path comprises a single input capacitor C₁ and a single feedback capacitor C₂.

In the embodiment of FIG. 7, each of the I path and Q path comprises two sub-path, named in general as known I path and I bar path, respectively Q path and Q bar path, wherein the term “bar” indicates the negative (minus) part of the processed signal.

The electric circuit 20 of FIG. 7 comprises also a (not illustrated) local oscillator connected to the electric circuit and arranged to generate a carrier signal having a carrier frequency and a (not illustrated) command module.

This command module is arranged to sequentially close each switch SW_{IP}, SW_{IM}, SW_{QP} and SW_{QM} during a mixer's averaging window, so that a RF signal coming from the LNA (via the capacitor C₃ in the example of FIG. 7) having a frequency close to the carrier frequency results in a non-zero down-converted signal across each input capacitor C₁, this down-converted signal being then amplified by each operational amplifier OA1, OA2, so that an amplified down-converted signal appears at the output of each operational amplifier OA1, OA2.

In the embodiment of FIG. 7, each of the I and Q path comprises two switches (SW_{IP} and SW_{IM} respectively SW_{QP} and SW_{QM}), then there are four switches: the mixer's averaging window is equal to a quarter of the carrier period (T_{LO}/4). Therefore, a first switch will be closed during the first quarter of the carrier period (the other three switches being open), a second switch will be closed during the second quarter of the carrier period (the other three switches being open), a third switch will be closed during the third quarter of the carrier period (the other three switches being open) and a fourth switch will be closed during the fourth quarter of the carrier period (the other three switches being open), those four quarters of the carrier period being not overlapping.

In the electric circuit 20 of FIG. 7, the voltage gain from the input capacitors C₁ to the output of the operational amplifier is equal to C₁/C₂, wherein C₂ is the feedback capacitor.

In one embodiment, the feedback capacitor(s) C₂ is(are) variable feedback capacitor(s), so as to have a variable gain.

In one embodiment, by controlling the variable feedback capacitor, the gain from RF to the frequency translated I/Q outputs can be set to 18 dB, 12 dB or 6 dB.

In the embodiment of FIG. 7, at least one (large) bias resistor R_{B} (four in the example of FIG. 7) is connected to the inputs of each operational amplifier OA1, OA2, so as to DC-bias the operational amplifier inputs, e.g. by setting a common-mode level at the operational amplifier inputs.

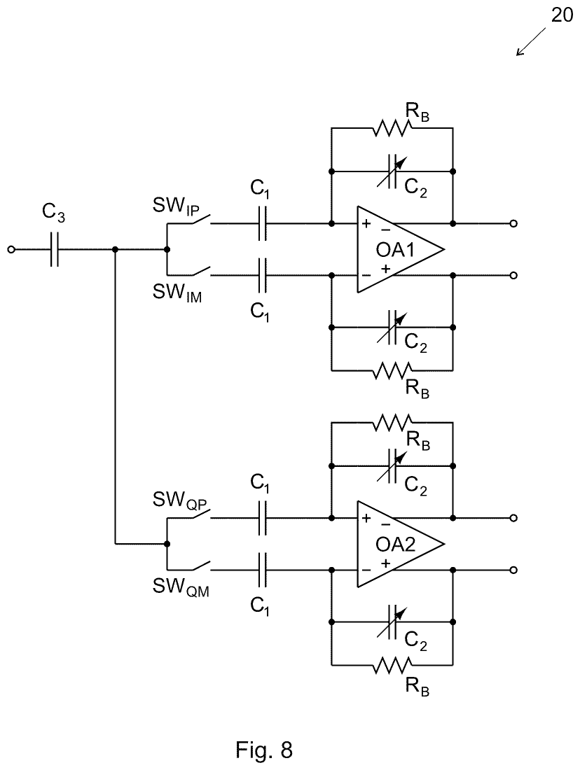

FIG. 8 illustrates another embodiment of the electric circuit 20 according to the invention. The embodiment of FIG. 8 can be at least partially combined with the embodiment of FIG. 7.

In this embodiment, a (large) feedback resistor(s) R_{B} is(are)across each feedback capacitor(s) C₂, so as to DC-bias the operational amplifier inputs. This embodiment is not related to the fact that each operational amplifier OA1 respectively OA2 is a fully differential operational amplifier and works also with non-fully differential operational amplifiers.

The presence of (large) feedback resistor(s) R_{B} allows to introduce a zero (at zero frequency) and a pole (at 1/(R_{B}C₂)) in the baseband (or IF) signal transfer function.

In one embodiment, the feedback resistor(s) R_{B} is(are) selected so that a pole ω in a frequency translated signal transfer function is at least 5 times lower in frequency than the wanted frequency translated signal for the gain settings, according to the following formula:

$$ω > \frac{5}{{R}_{B} {C}_{2}} \qquad ( 11 )$$

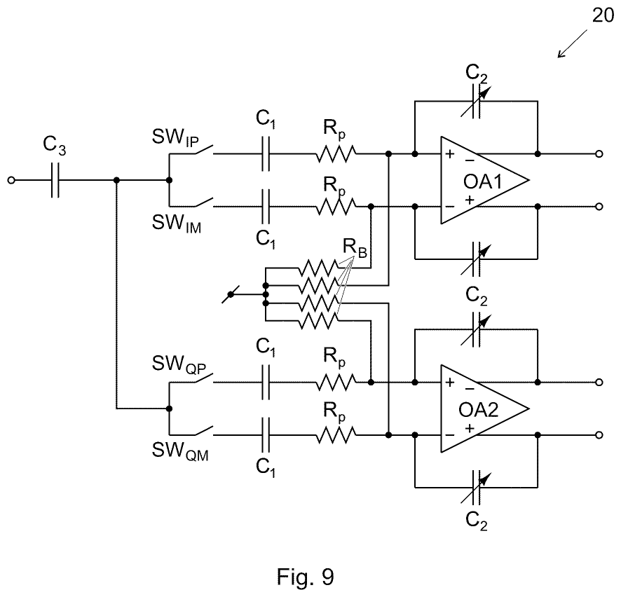

FIG. 9 illustrates another embodiment of the electric circuit 20 according to the invention. The embodiment of FIG. 9 can be at least partially combined with the embodiment of FIG. 8, i.e. the bias resistors R_{B} could be (in complement or alternative) placed across feedback each capacitor(s) C₂.

In the embodiment of FIG. 9, the electric circuit 20 comprises a resistor Rₚ between each switch SW_{IP}, SW_{IM}, SW_{QP}, SW_{QM} and the corresponding input of the operational amplifier OA1 respectively OA2, so as to introduce a pole in the frequency translated transfer function. This embodiment is not related to the fact that each operational amplifier OA1 respectively OA2 is a fully differential operational amplifier and works also with non-fully differential operational amplifiers. In one embodiment, the resistor Rₚ is between a switch and the corresponding capacitor without altering the operation of the electric circuit.

This embodiment is particularly advantageous as a first-order filter can be embedded in the electric circuit having the transfer function indicated in the following formula:

$$H ( s ) = ( - \frac{{C}_{1}}{{C}_{2}} ) \frac{1}{1 + {sR}_{p} {C}_{1}} \qquad ( 12 )$$

The pole of formula (12) can be used as part of the baseband (or IF) filtering if needed at the expense of gain and noise. This helps to simplify the design of the baseband filter and reduces the overall power dissipation.

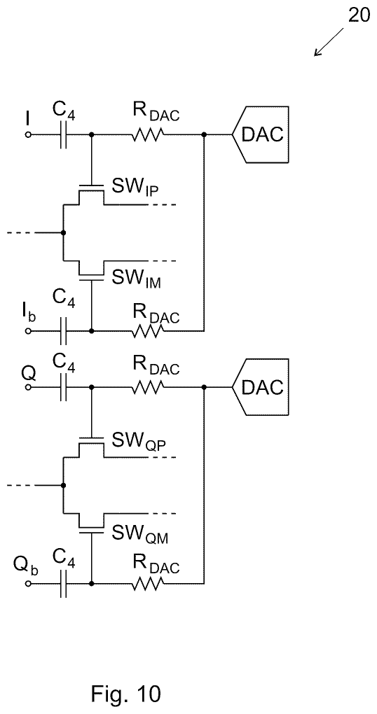

FIG. 10 illustrates an embodiment of how to drive the switches of the electric circuit 20 according to the invention.

In one embodiment, the switches have a low or zero on-resistance, and are arranged to turn off well (good isolation). A practical implementation uses MOS devices as switches.

The carrier clocks I, I_{b}, Q and Q_{b} may be coupled directly to the gates of the electric circuit switches SW_{IP}, SW_{IM}, SW_{QP}, SW_{QM} (embodiment not illustrated).

Alternatively, for optimum operation, they are AC-coupled to the gates of the switches SW_{IP}, SW_{IM}, SW_{QP}, SW_{QM} as illustrated in the FIG. 10.

In one preferred embodiment, the DC-level at the gates of the switches SW_{IP}, SW_{IM}, SW_{QP}, SW_{QM} may be controlled by a common (not illustrated) or two separate DACs, as illustrated in FIG. 10, which can be coupled to the gates by resistors R_{DAC}.

Controlling of this DC-level allows for optimum operation of the electric circuit switches SW_{IP}, SW_{IM}, SW_{QP}, SW_{QM}.

The present invention also concerns a RF receiver front-end 1, comprising:
an LNA 10,
the electric circuit 20 according to the invention, connected to an output of the LNA.

In one embodiment, the LNA can be any known LNA.

In another embodiment, the LNA can be a new and inventive LNA, which will be described in the following.

According to an independent aspect of the invention, the following described LNA is independent of the use of the electric circuit according to the invention.

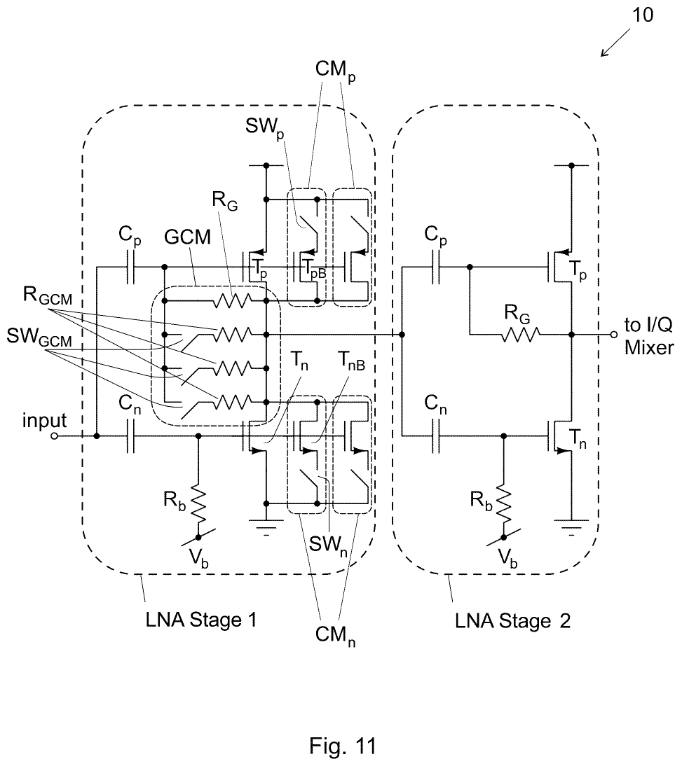

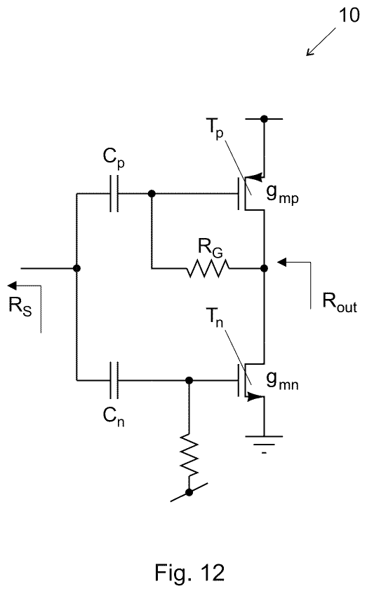

Embodiments of this LNA 10 are visible in FIGS. 11 and 12.

This LNA 10 comprises (at least one) current-reuse common-source stage (e.g. the LNA stage 1 in FIG. 11), the current-reuse common-source stage comprising:
a p-type transistor Tₚ,
a n-type transistor Tₙ sharing a variable current with the p-type transistor Tₚ,
a gain resistor R_{G} between a gate and a drain of the p-type transistor Tₚ,
a first capacitor Cₚ connected to the gate of the p-type transistor Tₚ,
a second capacitor Cₙ connected to the gate of the n-type transistor Tₙ.

The current-reuse common-source stage comprises also
a p-type bias voltage control module CMₚ, comprising a first switch SWₚ and a p-type bias voltage transistor T_{pB}, the first switch SWₚ being between a source terminal of the p-type bias voltage transistor T_{pB} and a source terminal of the p-type transistor Tₚ, a gate and a drain of the p-type bias voltage transistor T_{pB} being connected to the gate and the drain of the p-type transistor Tₚ,
a n-type bias voltage control module CMₙ, comprising a second switch SWₙ and a n-type bias voltage transistor T_{nB}, the second switch SWₙ being between a source terminal of the n-type bias voltage transistor T_{nB} and a source terminal of the n-type transistor Tₙ, a gate and a drain of the n-type bias voltage transistor T_{nB} being connected to a gate and a drain of the n-type transistor Tₙ.

The LNA comprises also a LNA command module (not illustrated) arranged to control the first switch SWₚ and the second switch SWₙ, so as to operate the current-reuse common-source stage under constant current density, so as to obtain a constant linearity.

This LNA command module could be the same command module of the electric circuit 20 or a different command module.

This LNA 10 presents many advantages: first, it is devoid of inductors. Since the electric circuit 20 is also devoid of inductors, the RF receiver front-end silicon area is drastically reduced since the RF receiver front-end 1 is an inductor-less RF receiver front-end.

Second, the LNA 10 is arranged to operate at constant current density to optimize linearity.

In one embodiment, the LNA comprises at least two p-type bias voltage control modules CMₚ and/or at least two n-type bias voltage control modules CMₙ. In the embodiment of FIG. 11, it comprises two p-type bias voltage control modules CMₚ and two n-type bias voltage control modules CMₙ.

For example, if the current of the LNA 10 is 100 μA, then no switches of the bias voltage control modules CMₚ respectively CMₙ are closed. If the current triples (it raises to 300 μA), then the switch of only one voltage control module CMₚ and of only one voltage control module CMₙ are closed by the LNA command module, so as to triple (×3) the global channel width W (i.e. the sum of the channel width p/n-type transistor plus the channel width of the p/n-type bias voltage transistor), so that the current density is kept constant.

If the current increases sixfold (it raises to 600 μA), then the switch of two voltage control modules CMₚ and of two voltage control module CMₙ are closed by the LNA command module, so as to increase sixfold (×6) the global channel width W (i.e. the sum of the channel width p/n-type transistor plus the channel width of the first p/n-type bias voltage transistor plus the channel width of the second p/n-type bias voltage transistor), so that the current density is kept constant.

Third, bias current control of the LNA allows to tradeoff power dissipation for sensitivity. In other words, it is possible to maintain a known sensitivity performance, while reducing power dissipation.

In one embodiment, illustrated in FIG. 11, the current-reuse common-source stage comprises a gain control module GCM comprising at least one (e.g. four as in the example of FIG. 11) gain control resistor R_{GCM} in series with a third switch SW_{GCM}, the series of the gain control resistor R_{GCM} with the third switch SW_{GCM} being in parallel to the gain resistor R_{G}.

In one embodiment, the resistors R_{G} and R_{GCM} also bias the PMOS devices of the LNA Stage 1.

Typical but non-limitative values of the gain obtained by the gain control module GCM are −6 dB, −12 dB and −18 dB.

Typical but non-limitative values of the total gain of the LNA Stages 1 and 2 is about 30 dB.

In the embodiment of FIG. 11, the LNA comprises two, complementary current-reuse common-source stages in series (LNA stage 1 and LNA stage 2), wherein the second is devoid of n-type and p-type bias voltage control modules. In another (not illustrated) embodiment, the second stage comprises also n-type and p-type bias voltage control modules.

In general, the bias current in the LNA stage 1 is traded-off for sensitivity, and the LNA stage 2 is more optimized for linearity. LNA stage 2 also allows to drive the mixer with an elevated impedance (a few hundred Ohms), which in general is beneficial for both the noise and the linearity performance of the mixer.

In the embodiment of FIG. 11, bias voltage via resistors R_{B} sets the operating current. Current dissipation (and performance) is controlled by the first and second switches SWₚ and SWₙ of the bias voltage control modules CMₚ respectively CMₙ.

FIG. 12 illustrates an embodiment of a part of a stage of the LNA (the bias control modules CMₚ and CMₙ being not illustrated).

Performance metrics as the total gain G, the input resistance Rᵢₙ, the output resistance Rₒᵤₜ and the noise figure NF of each stage are given by the following formulas:

$$G \approx \frac{- {g}_{m} {R}_{G}}{1 + {g}_{m} {R}_{s}} \qquad ( 13 )$$

$${R}_{in} \approx \frac{1}{{g}_{m}} ( 1 + \frac{{R}_{G}}{{r}_{o}} ) \qquad ( 14 )$$

$${R}_{out} \approx \frac{{R}_{G} + {R}_{s}}{1 + {g}_{m} {R}_{s}} // {r}_{o} \qquad ( 15 )$$

$$NF \approx 1 + γ + \frac{4}{{g}_{m} {R}_{G}} \qquad ( 16 )$$

wherein
gₘₙ is the transconductance of the N-device Tₙ
gₘₚ is the transconductance of the P-device Tₚ
gₘ is the combined transconductance of the N- and P-devices

(gₘ=gₘₙ+gₘₚ)
R_{S} is the output of the previous stage
rₒ is the parallel combination of the N- and P-devices output impedance
γ is a process parameter (γ≤1), see (17) below.

Current reuse maximizes the stage transconductance for a given current.

Capacitors Cₚ and Cₙ are assumed to be large (small impedance in the frequency range of operation).

Drain noise current in each device is modelled as:

$$\overline{{ι}_{n}^{2}} = 4 kT γ {g}_{m} \qquad ( 17 )$$

wherein
k is Boltzmann's constant
T is the absolute temperature
γ is a process parameter (γ≤1).

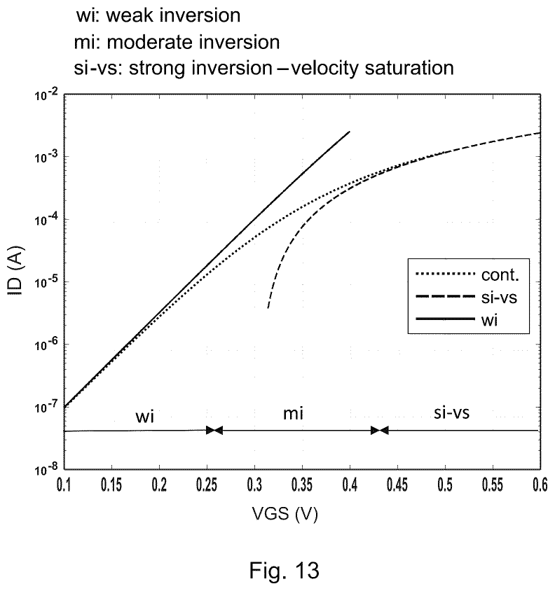

FIG. 13 illustrates the drain current I_{D} of an embodiment of the LNA MOS device of the RF receiver front-end according to the invention, as a function of the gate-source voltage V_{GS} of this LNA MOS device, for showing a general continuous model for a LNA MOS device.

Continuous MOS device model is shown by the following known formulas:

$${I}_{D} = {K}^{′} \frac{{X}^{2}}{1 + θ X} \qquad ( 18 )$$

$${K}^{′} = ( \frac{1}{2 n} μ {C}_{ox} ) \frac{W}{L} \qquad ( 19 )$$

$$X = 2 n {ϕ}_{t} \cdot ln ( 1 = {e}^{v} ) \qquad ( 20 )$$

$$v = \frac{{V}_{GS} - {V}_{T}}{2 n {ϕ}_{t}} \qquad ( 21 )$$

Specific examples for W=10 μm and L=0,05 μm are:

$${K}^{′} = 195 \frac{10}{0.05} ( \frac{μ A}{{V}^{2}} ) , {V}_{T} = 0.3 ( V ) , θ = 1.35 ( \frac{1}{V} ) ,$$

$$n = 1.1 and {ϕ}_{t} = 0.026 ( V )$$

In one embodiment, the p-type transistor and the n-type transistor are operated in a moderate inversion mi (e.g. the moderate inversion illustrated in FIG. 13), so as to optimize the IIP3 of the LNA.

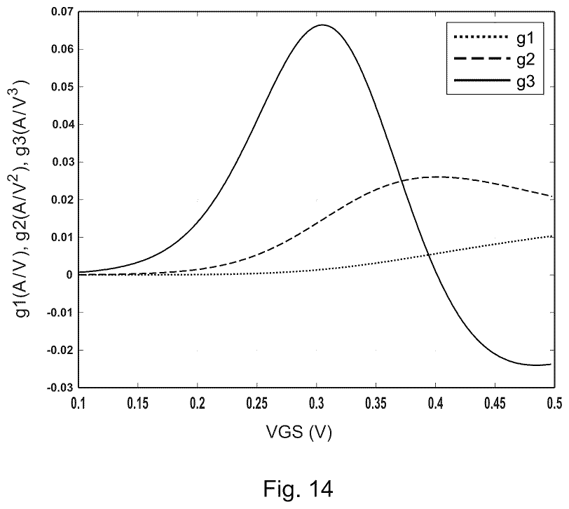

FIG. 14 illustrates the first-order transconductance g₁, the second-order transconductance g₂ and the third-order transconductance g₃ of an embodiment of the LNA devices of the RF receiver front-end according to the invention, as a function of the gate-source voltage V_{GS}.

Small-signal device current ip can be expanded in a series for small-signal linearity estimation and expressed as a function of the small-signal gate-source voltage v_{gs} as following:

$${i}_{D} = {g}_{1} {v}_{gs} + {g}_{2} {v}_{gs}^{2} + {g}_{3} {v}_{gs}^{3} \qquad ( 22 )$$

Device linearity figures IIP2 and IIP3 can be estimated from the following formulas:

$$llP 2 = \vert \frac{{g}_{1}}{{g}_{2}} \vert \qquad ( 23 )$$

$$llP 3 = \sqrt{\frac{4}{3} \vert \frac{{g}_{1}}{{g}_{3}} \vert} \qquad ( 24 )$$

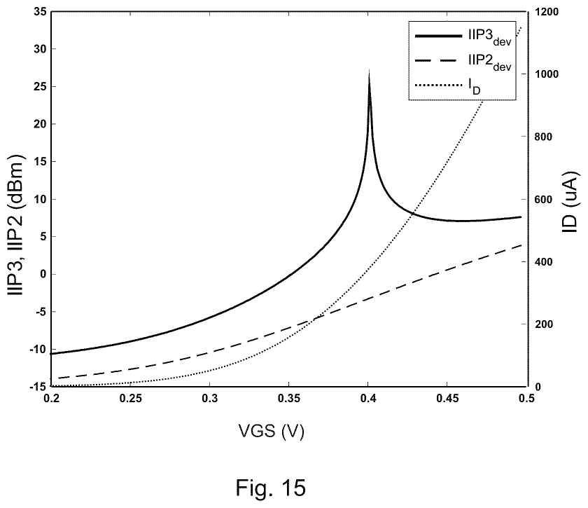

FIG. 15 illustrates the IIP3, IIP2 and the drain current of an embodiment of the LNA devices of the RF receiver front-end according to the invention, as a function of the gate-source voltage of these LNA devices.

Device IIP3 is expected to peak when g₃ crosses zero, as illustrated by considering both FIGS. 14 and 15.

Therefore, in one embodiment the optimum LNA IIP3 is achieved in upper moderate inversion towards the onset of strong inversion.

In one embodiment, the LNA IIP2 increases monotonically with power dissipation.

In one embodiment, decreasing LNA transistors' length moves the optimum IIP3 point towards lower V_{GS} (for similar gₘ/l ratio). This decreases the LNA capacitance, but increases thermal noise, as γ increases.

In one embodiment, changing LNA transistors' width to keep the LNA linearity constant as the bias current is changing, the device should operate at a set current density given by the following formula:

$$\frac{{I}_{D}}{W} = ( \frac{1}{2 n} μ {C}_{ox} ) \frac{1}{L} \cdot \frac{{X}^{2}}{1 + θ X} \qquad ( 25 )$$

wherein
I_{D} is he LNA transistor current
W is the total channel width of the (p- or n-type) transistor
L is the channel length of the (p- or n-type) LNA transistor
μ, Cₒₓ, n, θ are known process parameters.

For specific channel length L, the right-hand side in the equation above depends only on V_{GS}, and the thermal voltage φₜ. Therefore, IIP2 and IIP3 remain constant if I_{D} and W are ratioed together with constant V_{GS}.

In one embodiment, the front-end comprises a baseband (or IF) amplifier, connected to an output of the electric circuit and arranged so as to provide a baseband (or IF) gain depending on the LNA gain and on the electric circuit gain, so as to have e.g. a given total gain of the front-end.

In one embodiment, the baseband (or IF) amplifier is a baseband (or IF) filter.

In one embodiment, this baseband (or IF) filter is a known baseband (or IF) filter providing a gain.

In another embodiment, this baseband (or IF) filter can be a new and inventive baseband (or IF) filter, which will be described in the following.

According to an independent aspect of the invention, the following described baseband (or IF) filter is independent on the use of the electric circuit and/or of the LNA according to the invention.

In one embodiment, this baseband (or IF) filter is arranged to be configured as a two pole filter, as a single pole filter or it can be bypassed, so as to trade-off its sharpness for power dissipation. In this embodiment, the baseband (or IF) filter has then a reconfigurable topology that saves power in the analog baseband (or IF) at the expense of the carrier to interference ratio (C/I) and/or alias attenuation.

In one embodiment, the two pole filter is a polynomial filter, e.g. a Tow-Thomas filter, a voltage-controlled voltage-source (VCVS) filter or controlled-source filter such as a Sallen-Key filter.

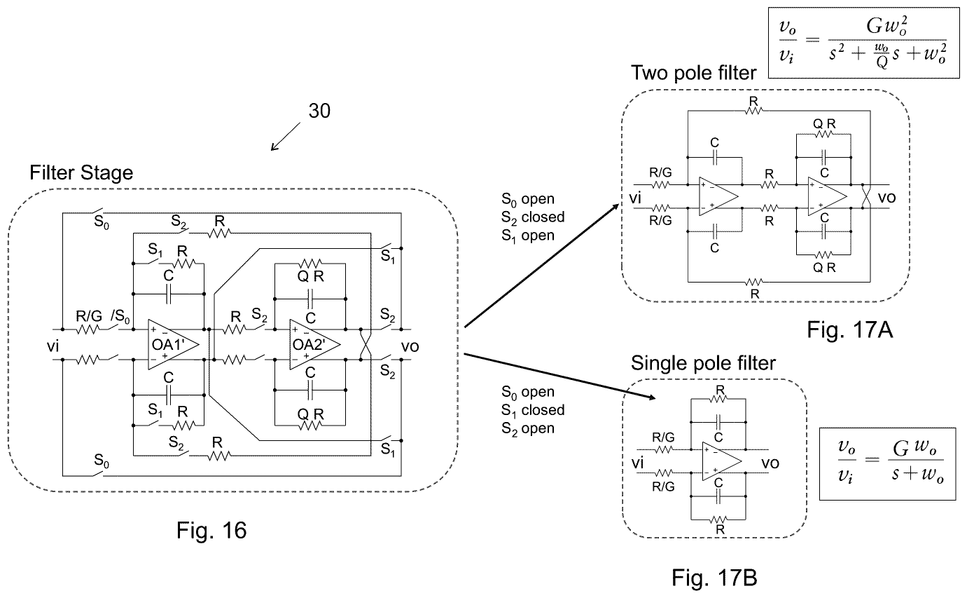

FIG. 16 illustrates an embodiment of a baseband (or IF) filter 30 according to the invention. It comprises two operational amplifiers OA1′ and OA2′, which in FIG. 16 are fully differential (although this is not necessary for the working of the baseband (or IF) filter 30).

The baseband (or IF) filter 30 comprise a baseband (or IF) command module (not illustrated) arranged to open/close switches S₀, /S₀, S₁ and S₂. The switch S₀ directly links the input to the output of the baseband (or IF) filter 30. The working of the switch /S₀, which precedes the first operational amplifiers OA1′, is complementary to the working of the switch S₀: therefore, once the switch S₀ is closed, the switch /S₀ is open and vice-versa.

In one embodiment, the baseband (or IF) command module is arranged so as to close the switch S₀ (and therefore open the switch /S₀): this allows to completely by-pass the filter stage 30. In this case, preferably the switches S₁ and S₂ are open, so as to avoid the dissipation power by the operational amplifiers OA1′ and OA2′. Also the operational amplifiers are powered down.

In the embodiment of FIG. 16, the (differential) input of the filter 30 is followed by a resistor having value R/G, wherein G is the gain of the filter 30, in series with the switch /S₀ and the (differential) input of the first (differential) operational amplifier OA1′. The operational amplifier OA1′ can form with the feedback capacitor C and the resistor R (this last being in parallel to the feedback capacitor C and in series with a switch S₁) a lossless integrator, once the switch S₁ is open.

Another resistor R in series with a switch S₂ connects each output of the first (differential) operational amplifier OA1′ to the input of the second (differential) operational amplifier OA2′. The operational amplifier OA2′ forms with the feedback capacitor C and the resistor having value QR (Q being the filter quality factor) a lossy integrator.

Each output of the second (differential) operational amplifier OA2′ is connected to the respective output of the filter 30 via a switch S₂.

Each output of the first (differential) operational amplifier OA1′ is connected to the alternative output of the filter 30 via a switch S₁.

Each input of the first (differential) operational amplifier OA1′ is connected to the alternative output of the second (differential) operational amplifier OA2′ via a switch S₂ in series with a resistor R.

In a first possible configuration of the baseband (or IF) filter of FIG. 16, illustrated in FIG. 17A, the command module is arranged so as to:
open the switch S₀ (and therefore close the switch/S₀),
open the switches S₁,
close the switches S₂.

In this configuration, this baseband (or IF) filter is a two pole filter.

In one embodiment, the two pole filter is a polynomial filter, e.g. a Tow-Thomas filter, a voltage-controlled voltage-source (VCVS) filter or controlled-source filter such as a Sallen-Key filter.

In the embodiment of FIG. 17A, the two pole filter is a Tow-Thomas filter, with a natural frequency ω₀=1/(RC).

In the embodiment of FIG. 17A, the filter comprises two integrators, with the second one comprises a feedback resistor having its value multiplied by the quality factor Q of the filter, for improving the filter noise performances. In other words, the Tow-Thomas filter is arranged to have the lossless integrator first for reduced noise.

FIG. 17B illustrates a second possible configuration of the baseband (or IF) filter of FIG. 16.

In this configuration, this baseband (or IF) filter is a single pole filter with a corner frequency ω₀=1/(RC).

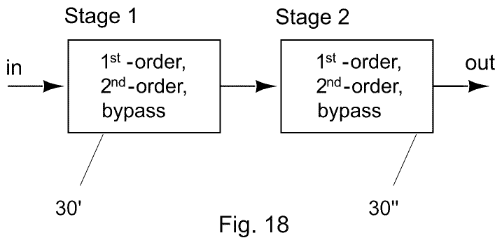

FIG. 18 illustrates another embodiment of the baseband (or IF) filter of the RF receiver front-end according to one embodiment of the invention.

In this embodiment, the baseband (or IF) filter is a first stage baseband (or IF) filter 30′ (which can be by-passed, morphed in a first order filter or morphed in a second order filter), the front-end comprising a second stage baseband (or IF) filter 30″ in series with the first stage baseband (or IF) filter (which can be by-passed, morphed in a first order filter or morphed in a second order filter).

In one embodiment, the first stage baseband (or IF) filter 30′ has a quality factor lower than the second stage 30″ baseband (or IF) filter to avoid peaking at the output of the first stage filter 30′.

In one embodiment, (at least) two filter stages 30′, 30″ are placed in series to achieve 1st-, 2nd-, 3rd- & 4th-order characteristic, e.g. according to the configuration table below:

TABLE 1

| Stage 1 | | Stage2 | | |
|---|---|---|---|---|
| Order | Q | Order | Q | Overall |
| 1 | — | bypass | — | Butterworth 1st |
| 2 | 0.707 | bypass | — | Butterworth 2nd |
| 2 | 1 | 1 | — | Butterworth 3rd |
| 2 | 0.541 | 2 | 1.307 | Butterworth 4th |

In one embodiment, each filter stage 30′, 30″ can provide 18 dB, 12 dB, 6 dB, 0 dB gain.

In one embodiment, when implementing a 4th-order Butterworth filter, the low-Q second order stage is placed first to avoid peaking in the internal node.

By summarizing, in an RF front-end comprising the electric circuit, the LNA and the baseband (or IF) filter according to the inventions, the following advantages can be obtained:
the front-end is inductor-less, which drastically reduces silicon area by eliminating the use of inductors,
current dissipation in the front-end is efficiently traded off for sensitivity while S11 remains under control
the active averaging mixer relaxes gain requirements in the baseband (or IF) filter,
the flexible, reconfigurable baseband (or IF) filter synthesizes up to 4^{th}-order responses for demanding C/I applications, and permits to aggressively reduce power when C/I performance can be allowed to degrade,
it is possible to obtain the same sensitivity of known front-end with 6% lower power and similar C/I performance,
1.8 dB sensitivity hit with 18% lower power and similar C/I performance,
1.8 dB sensitivity hit with up to 42% lower power in applications where C/I can be allowed to degrade.

1. An electric circuit providing mixing and gaining functions for a RF receiver front-end, the electric circuit comprising an I path and a Q path, wherein each of the I path and the Q path comprises:
a switch,
an input capacitor between the switch and an input of an operational amplifier,
the operational amplifier,
a feedback capacitor between the input and the output of the operational amplifier,
the electric circuit comprising:
a bias resistor so as to DC-bias the operational amplifier input,
a local oscillator arranged to generate a carrier signal having a carrier frequency,
a command module arranged to sequentially close each switch during a mixer's averaging window, so that an incoming signal having a frequency close to the carrier frequency, i.e. a frequency belonging to a mixer's bandwidth, results in a non-zero down-converted signal across the input capacitor, this down-converted signal being then amplified by the operational amplifier so that an amplified down-converted signal appears at the output of the operational amplifier, wherein the electric circuit comprises a resistor between each input capacitor and the corresponding input of the operational amplifier, so as to introduce a pole in the baseband or IF transfer function.

2. The electric circuit of claim 1, wherein the mixer bandwidth is given by the formula:
$$BW = 2 \frac{1}{2 π \cdot 4 ( {R}_{S} + {R}_{SW} ) {C}_{1}} ,$$
wherein
R_{S} is the resistance of a source resistor connected to the switch,
R_{SW} is the resistance of each switch once it is closed
C₁ is the capacitance of each input capacitor.

3. The electric circuit of claim 1, wherein the operational amplifier is a fully differential operational amplifier, wherein the switch is a first switch, wherein the input capacitor is a first input capacitor, wherein the input is a first input, wherein the output is a first output, wherein the mixer's averaging window is a first mixer's averaging window, wherein each of the I path and the Q path comprises:
a second switch,
a second input capacitor between the second switch and a second input of the differential operational amplifier,
a second feedback capacitor between the second input and a second output of the operational amplifier,
wherein the command module is arranged to sequentially close each switch during a second mixer's averaging window, so that said incoming signal results in a non-zero down-converted signal across the input capacitors , this down-converted signal being then amplified by the differential operational amplifier so that an amplified down-converted signal appears at the first and second outputs of the differential operational amplifier.

4. The electric circuit of claim 1, wherein the bias resistor is placed at the operational amplifier input(s) and/or wherein the bias resistor is a feedback resistor across each feedback capacitor(s).

5. The electric circuit of claim 4, wherein the feedback resistor(s) is(are) selected so that a pole in a baseband or IF signal transfer function is at least five times lower in frequency than the wanted baseband or IF signal for the gain settings.

6. The electric circuit of claim 1, wherein a gate of each switch is coupled, preferably AC-coupled, to the local oscillators.

7. A front-end of a RF receiver, comprising:
an LNA,
the electric circuit of claim 1, connected to an output of the LNA.

8. The front-end of claim 7, wherein the LNA comprises a current-reuse common-source stage, the current-reuse common-source stage comprising:
a p-type transistor,
a n-type transistor sharing a variable current with the p-type transistor,
a gain resistor between a gate and a drain of the p-type transistor,
a first capacitor connected to the gate of the p-type transistor,
a second capacitor connected to the gate of the n-type transistor,
a p-type bias voltage control module, comprising a first switch and a p-type bias voltage transistor, the first switch being between a source terminal of the p-type bias voltage transistor and a source terminal of the p-type transistor, a gate and a drain of the p-type bias voltage transistor being connected to the gate and the drain of the p-type transistor,
a n-type bias voltage control module, comprising a second switch and a n-type bias voltage transistor, the second switch being between a source terminal of the n-type bias voltage transistor and a source terminal of the n-type transistor, a gate and a drain of the n-type bias voltage transistor being connected to a gate and a drain of the n-type transistor,
a LNA command module arranged to control the first switch and the second switch so as to operate the current-reuse common-source stage under constant current density, so as to obtain a constant linearity

9. The front-end of claim 8, wherein the LNA comprises at least two p-type bias voltage control modules and/or at least two n-type bias voltage control modules.

10. The front-end of claim 8, wherein the current-reuse common-source stage comprises a gain control module, wherein the gain control module comprises at least one gain control resistor in series with a third switch, the series of the gain control resistor with the third switch being in parallel to the gain resistor.

11. The front-end of claim 8, wherein the p-type transistor and the n-type transistor are operated in a moderate inversion, so as to optimize an IIP3 of the LNA.

12. The front-end of claim 7, comprising a baseband or IF amplifier, connected to an output of the electric circuit and arranged so as to provide a baseband or IF gain depending on the LNA gain and on the electric circuit gain.

13. The front-end of claim 12, the baseband or IF amplifier being a baseband or IF filter.

14. The front-end of claim 13, wherein the baseband or IF filter is arranged to be configured as a two pole filter, as a single pole filter or it can be bypassed, so as to trade-off its sharpness for power dissipation and/or wherein the baseband or IF filter is a first stage baseband or IF filter, the front-end comprising a second stage baseband or IF filter in series with the first stage baseband or IF filter.
